(19) United States
(12) Patent Application Publication
(10) Pub. No.: US 2025/0031442 A1
(43) Pub. Date: Jan. 23, 2025

(54) SEMICONDUCTOR DEVICE

(71) Applicant: SAMSUNG ELECTRONICS CO., LTD., Suwon-si (KR)

(72) Inventors: Ji Won Park, Suwon-si (KR); Min Seok Jo, Suwon-si (KR); Woo Sung Park, Suwon-si (KR); Jun-Youp Lee, Suwon-si (KR); Jin Young Choi, Suwon-si (KR)

(21) Appl. No.: 18/423,117

(22) Filed: Jan. 25, 2024

(30) Foreign Application Priority Data
Jul. 18, 2023 (KR) 10-2023-0092856

(51) Int. Cl. H01L 27/092; H01L 23/528; H01L 29/06; H01L 29/417; H01L 29/423; H01L 29/775

(52) U.S. Cl. CPC H01L 27/092; H01L 23/5286; H01L 29/0673; H01L 29/41733; H01L 29/42392; H01L 29/775

(57) ABSTRACT

A semiconductor device includes a first substrate having a first surface and a second opposite surface, a first lower interlayer insulating layer on the second surface, a first active pattern including a first lower pattern contacting the first surface, a plurality of first sheet patterns spaced apart from the first lower pattern in a second direction, a first gate structure on the first lower pattern, a first source/drain pattern on a side of the first gate structure, a second lower interlayer insulating layer including a third surface and a fourth opposite surface, a second active pattern including a second lower pattern contacting the third surface, a plurality of second sheet patterns spaced apart from the second lower pattern in the second direction, a second gate structure on the second lower pattern, wherein the first lower pattern has a first height, and the second lower pattern has a second different height.

### CROSS-REFERENCE TO RELATED APPLICATION

This application claims priority from Korean Patent Application No. 10-2023-0092856, filed on Jul. 18, 2023, in the Korean Intellectual Property Office, the disclosure of which is incorporated by reference in its entirety.

### BACKGROUND

The present disclosure relates to a semiconductor device that includes a multi-bridge channel field effect transistor (MBCFET™).

### DESCRIPTION OF THE RELATED ART

As one of the scaling techniques for increasing a density of a semiconductor device, a multi-gate transistor for forming a multi-channel active pattern (or silicon body) of a fin or nanowire shape on a substrate and forming a gate on a surface of the multi-channel active pattern has been suggested. Since the multi-gate transistor uses a three-dimensional channel, it is easy to scale the multi-gate transistor. Also, even though a gate length of the multi-gate transistor is not increased, a current control capability may be improved. In addition, a short channel effect (SCE) in which a potential of a channel region is affected by a drain voltage may be effectively suppressed. As a pitch size of a semiconductor device is reduced, capacitance reduction and ensuring electrical stability between contacts in the semiconductor device is necessary.

### SUMMARY

In general, in some aspects, the present disclosure is directed toa semiconductor device that can improve element performance and reliability.

According to some aspects of the present disclosure, a semiconductor device comprises a first substrate including a first surface and a second surface opposite to the first surface, a first lower interlayer insulating layer disposed on the second surface of the first substrate, a first active pattern including a first lower pattern being in contact with the first surface of the first substrate, extended in a first direction and a plurality of first sheet patterns spaced apart from the first lower pattern in a second direction, a first gate structure disposed on the first lower pattern, surrounding the plurality of first sheet patterns, a first source/drain pattern disposed on at least one side of the first gate structure, a second lower interlayer insulating layer including a third surface and a fourth surface opposite to the third surface, a second active pattern including a second lower pattern being in contact with the third surface of the second lower interlayer insulating layer, extended in the first direction and a plurality of second sheet patterns spaced apart from the second lower pattern in the second direction, a second gate structure disposed on the second lower pattern, surrounding the plurality of second sheet patterns and a second source/drain pattern disposed on at least one side of the second gate structure, wherein the first lower pattern has a first height based on the first surface of the first substrate, and the second lower pattern has a second height different from the first height based on the third surface of the second lower interlayer insulating layer.

According to some aspects of the present disclosure, a semiconductor device comprises a first active pattern including a first lower pattern extended in a first direction and a plurality of first sheet patterns spaced apart from the first lower pattern in a second direction, a first trench defining the first lower pattern and having a first depth, a first gate structure disposed on the first lower pattern, surrounding the plurality of first sheet patterns, a first source/drain pattern disposed on at least one side of the first gate structure, a second active pattern including a second lower pattern extended in the first direction and a plurality of second sheet patterns spaced apart from the second lower pattern in the second direction, a second trench defining the second lower pattern and having a second depth greater than the first depth, a second gate structure disposed on the second lower pattern, surrounding the plurality of second sheet patterns and a second source/drain pattern disposed on at least one side of the second gate structure, wherein a width of the first gate structure in the first direction is smaller than that of the second gate structure in the first direction.

According to some aspects of the present disclosure, a semiconductor device comprises a first substrate including a first surface and a second surface opposite to the first surface and including an insulating material, a first active pattern including a first lower pattern being in contact with the first surface of the first substrate, extended in a first direction and a plurality of first sheet patterns spaced apart from the first lower pattern in a second direction, a first gate structure disposed on the first lower pattern, surrounding the plurality of first sheet patterns, a first source/drain pattern disposed on at least one side of the first gate structure, a first lower interlayer insulating layer disposed on the second surface of the first substrate, a first rear wiring line disposed in the first lower interlayer insulating layer and connected to the first source/drain pattern, a second lower interlayer insulating layer including a third surface and a fourth surface opposite to the third surface, a second active pattern including a second lower pattern being in contact with the second lower interlayer insulating layer, extended in the first direction and a plurality of second sheet patterns spaced apart from the second lower pattern in the second direction, a second gate structure disposed on the second lower pattern, surrounding the plurality of second sheet patterns, a second source/drain pattern disposed on at least one side of the second gate structure and a second rear wiring line disposed in the second lower interlayer insulating layer and connected to the second source/drain pattern, wherein the first lower pattern has a first height based on the first surface of the first substrate, the second lower pattern has a second height greater than the first height based on the third surface of the second lower interlayer insulating layer, and based on an upper surface of the first gate structure, a distance to an upper surface of the first lower pattern is the same as a distance to an upper surface of the second lower pattern.

### BRIEF DESCRIPTION OF THE DRAWINGS

Exemplary implementations will more clearly understood from the following detailed description, taken in conjunction with the accompanying drawings.

FIG. 1 is a layout view illustrating an example of a semiconductor device according to some implementations.

FIG. 2 is a cross-sectional view taken along lines A-A and B-B of FIG. 1.

FIG. 3 is a cross-sectional view taken along lines C-C and D-D of FIG. 1.

FIG. 4 is a cross-sectional view taken along line E-E of FIG. 1.

FIG. 5 is a cross-sectional view taken along line F-F of FIG. 1.

FIG. 6 is a view illustrating an example of a semiconductor device according to some implementations.

FIG. 7 is a view illustrating an example of a semiconductor device according to some implementations.

FIGS. 8 to 10 are views illustrating an example of a semiconductor device according to some implementations.

FIGS. 11 to 15 are views illustrating an example of a semiconductor device according to some implementations.

### DETAILED DESCRIPTION

It will be understood that, although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure.

A semiconductor device according to some implementations includes, but is not limited to, a fin-type transistor (FinFET) including a channel region of a fin-type pattern shape, a transistor including a nanowire or a nanosheet, or a multi-bridge channel field effect transistor (MBCFET™) by way of example.

The semiconductor device according to some implementations may include a tunneling transistor (tunneling FET), a three-dimensional (3D) transistor or a vertical transistor (Vertical FET). The semiconductor device according to some implementations may include a planar transistor. In addition, some implementations may be applied to two-dimensional (2D) material based transistors (FETs) and a heterogeneous structure thereof. In addition, the semiconductor device according to some implementations may include a bipolar junction transistor, a laterally diffused metal oxide semiconductor (LDMOS) transistor, and the like.

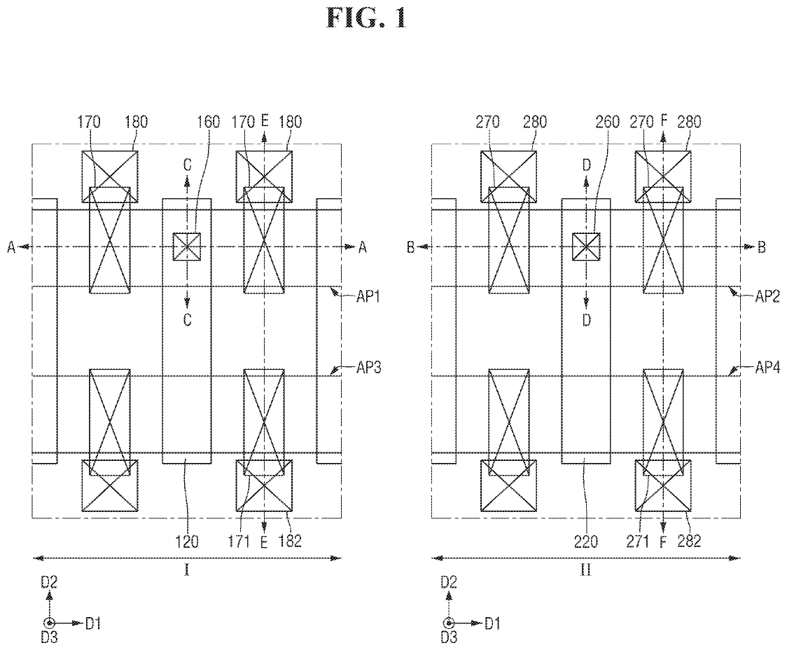

Hereinafter, exemplary implementations of a semiconductor device according to the present disclosure will be described with reference to FIGS. 1 to 5.

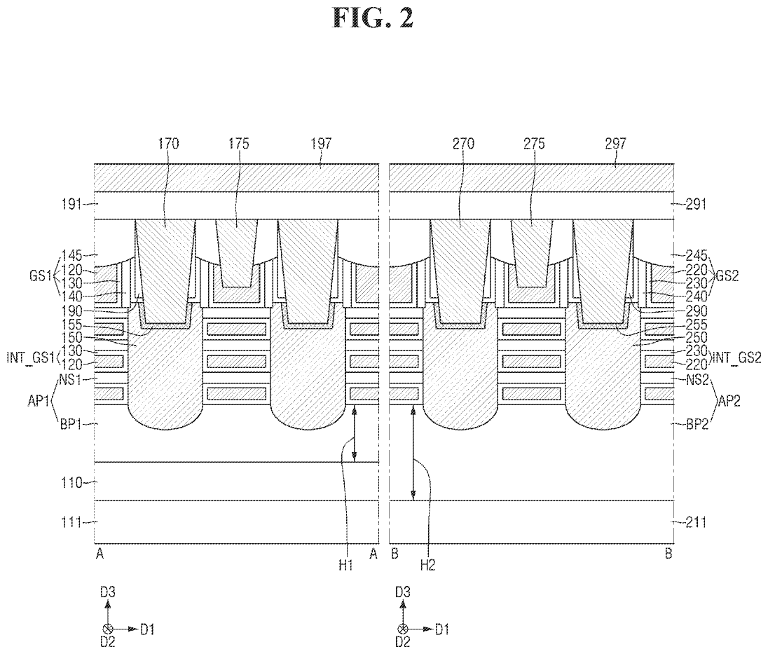

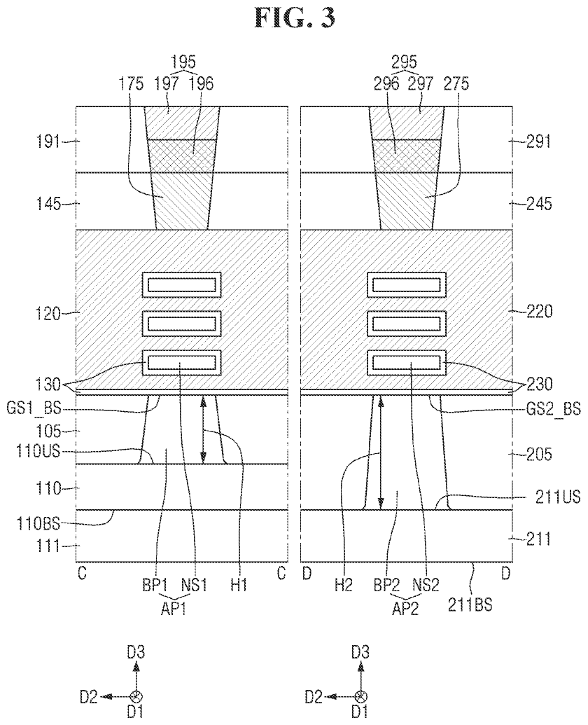

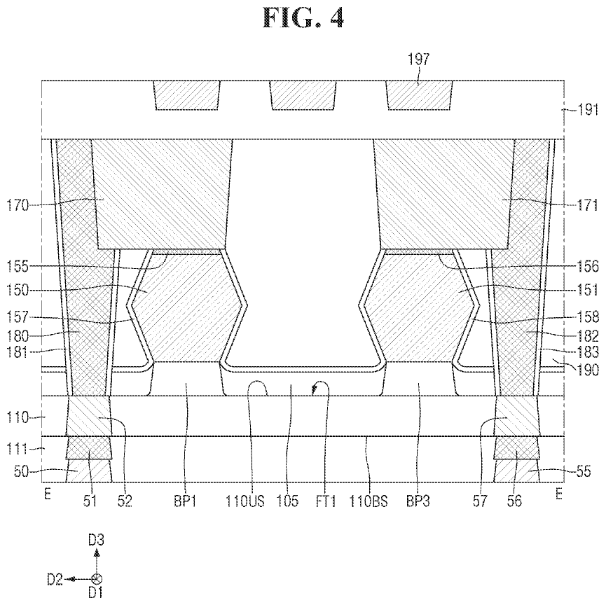

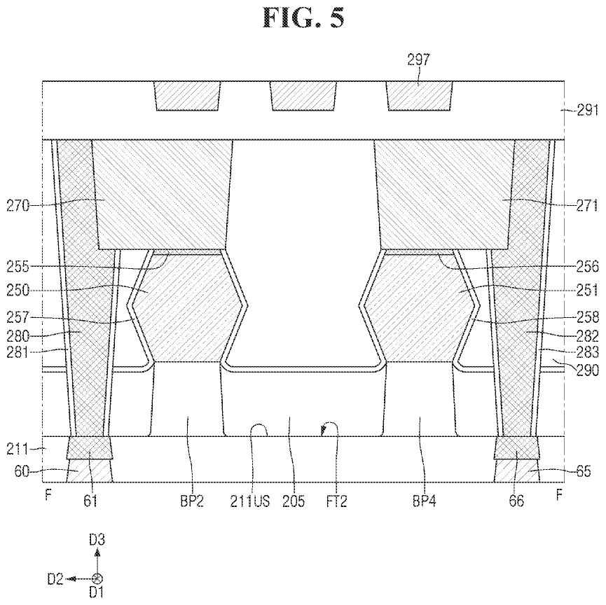

FIG. 1 is a layout view illustrating a semiconductor device according to some embodiments. FIG. 2 is a cross-sectional view taken along lines A-A and B-B of FIG. 1. FIG. 3 is a cross-sectional view taken along lines C-C and D-D of FIG. 1. FIG. 4 is a cross-sectional view taken along line E-E of FIG. 1. FIG. 5 is a cross-sectional view taken along line F-F of FIG. 1.

For convenience of description, a first rear wiring line 50 and a first front wiring line 197 are not shown in FIG. 1.

Referring to FIGS. 1-5, the semiconductor device according to some implementations includes a first active pattern AP1, a second active pattern AP2, a third active pattern AP3, a fourth active pattern AP4, a first rear wiring line 50, a second rear wiring line 60, a first substrate 110, a first lower interlayer insulating layer 111, a second lower interlayer insulating layer 211, a first gate structure GS1, a second gate structure GS2, a first source/drain pattern 150, a second source/drain pattern 250, a first source/drain contact 170, a second source/drain contact 270, a first contact connection via 180, and a second contact connection via 280.

The first substrate 110 may include a first surface 110US and a second surface 110BS, which are opposite to each other in a third direction D3. Since a first gate electrode 120 and the first source/drain pattern 150 may be disposed on the first surface 110US of the first substrate 110, the first surface 110US of the first substrate 110 may be an upper surface of the first substrate 110. The second surface 110BS of the first substrate 110, which is opposite to the first surface 110US of the first substrate 110, may be a lower surface of the first substrate 110. The first substrate 110 may include an insulating material. The first substrate 110 may include, for example, silicon oxide.

The first active pattern AP1 and the third active pattern AP3 may be disposed on the first substrate 110. For example, the first active pattern AP1 and the third active pattern AP3 may be disposed on the upper surface 110US of the first substrate 110. The first active pattern AP1 and the third active pattern AP3 may be extended in a first direction D1.

The first active pattern AP1 and the third active pattern AP3 may be spaced apart from each other in a second direction D2. The first active pattern AP1 may be disposed in a region in which a transistor of the same conductivity type is formed. The third active pattern AP3 may be disposed in a region in which a transistor of the same conductivity type is formed.

For example, the first active pattern AP1 may be disposed in a region in which a P-type transistor is formed. The third active pattern AP3 may be disposed in a region in which an N-type transistor is formed. However, the present implementation is not limited to this example.

The second lower interlayer insulating layer 211 may include a third surface 211US and a fourth surface 211BS, which are opposite to each other in the third direction D3. Since a second gate electrode 220 and the second source/drain pattern 250 may be disposed on the third surface 211US of the second lower interlayer insulating layer 211, the third surface 211US of the second lower interlayer insulating layer 211 may be an upper surface of the second lower interlayer insulating layer 211.

The second active pattern AP2 and the fourth active pattern AP4 may be disposed on the second lower interlayer insulating layer 211. For example, the second active pattern AP2 and the fourth active pattern AP4 may be disposed on the upper surface 211US of the second lower interlayer insulating layer 211. The second active pattern AP2 and the fourth active pattern AP4 may be extended lengthwise in the first direction D1.

The second active pattern AP2 and the fourth active pattern AP4 may be spaced apart from each other in the second direction D2. The second active pattern AP2 may be disposed in a region in which a transistor of the same conductivity type is formed. The fourth active pattern AP4 may be disposed in a region in which a transistor of the same conductivity type is formed.

In some implementations, the second active pattern AP2 may be disposed in a region in which a P-type transistor is formed. The fourth active pattern AP4 may be disposed in a region in which an N-type transistor is formed. Although the conductivity types of the transistors of the second active pattern AP2 and the fourth active pattern AP4 are described as being different from each other, the present implementation is not limited thereto. For example, in the semiconductor device according to some implementations, the second active pattern AP2 and the fourth active pattern AP4 may be regions in which transistors of the same conductivity type are formed.

The first active pattern AP1 and the third active pattern AP3 may be formed in a first region I. The second active pattern AP2 and the fourth active pattern AP4 may be formed in a second region II. In the semiconductor device according to some implementations, the first region I may be a region in which an active element is formed. The second region II may be a region in which a passive element is formed. However, the present implementation is not limited to the above example.

Each of the active patterns AP1, AP2, AP3 and AP4 may be a multi-channel active pattern. For example, the first active pattern AP1 may include a first lower pattern BP1 and a plurality of first sheet patterns NS1. The second active pattern AP2 may include a second lower pattern BP2 and a plurality of second sheet patterns NS2. Although not shown, the third active pattern AP3 may include a third lower pattern BP3 and a plurality of third sheet patterns. The fourth active pattern AP4 may include a fourth lower pattern BP4. Although not shown, the fourth active pattern AP4 may include a plurality of fourth sheet patterns. In the semiconductor device according to some implementations, each of the active patterns AP1, AP2, AP3 and AP4 may be an active pattern that includes a nanosheet or a nanowire.

The first lower pattern BP1 and the third lower pattern BP3 may be protruded from the first substrate 110. In some implementations, the first lower pattern BP1 and the third lower pattern BP3 may be protruded from the upper surface 110US of the first substrate 110. The first lower pattern BP1 and the third lower pattern BP3 may be fin-type patterns.

The second lower pattern BP2 and the fourth lower pattern BP4 may be protruded from the second lower interlayer insulating layer 211. In some implementations, the second lower pattern BP2 and the fourth lower pattern BP4 may be protruded from the upper surface 211US of the second lower interlayer insulating layer 211. The second lower pattern BP2 and the fourth lower pattern BP4 may be fin-type patterns.

The first lower pattern BP1 and the third lower pattern BP3 may be separated from each other by a first trench FT1. In some implementations, the upper surface 110US of the first substrate 110 may include a bottom surface of the first trench FT1. Each of the first lower pattern BP1 and the third lower pattern BP3 includes sidewalls extended in the first direction D1. The sidewalls of each of the first lower pattern BP1 and the third lower pattern BP3 may be defined by the first trench FT1.

The plurality of first sheet patterns NS1 may be disposed on the first lower pattern BP1. The plurality of first sheet patterns NS1 may be spaced apart from the first lower pattern BP1 in the third direction D3. The plurality of third sheet patterns may be disposed on the third lower pattern BP3. The plurality of third sheet patterns may be spaced apart from the third lower pattern BP3 in the third direction D3.

The second lower pattern BP2 and the fourth lower pattern BP4 may be separated from each other by a second trench FT2. In some implementations, the upper surface 211US of the second lower interlayer insulating layer 211 may include a bottom surface of the second trench FT2. Each of the second lower pattern BP2 and the fourth lower pattern BP4 includes sidewalls extended in the first direction D1. The sidewalls of each of the second lower pattern BP2 and the fourth lower pattern BP4 may be defined by the second trench FT2.

The plurality of second sheet patterns NS2 may be disposed on the second lower pattern BP2. The plurality of second sheet patterns NS2 may be spaced apart from the second lower pattern BP2 in the third direction D3. The plurality of fourth sheet patterns may be disposed on the fourth lower pattern BP4. The plurality of fourth sheet patterns may be spaced apart from the fourth lower pattern BP4 in the third direction D3.

In this case, the first direction D1 may cross the second direction D2 and the third direction D3. In addition, the second direction D2 may cross the third direction D3. The third direction D3 may be a thickness direction of the substrate 100.

The first lower pattern BP1 may have a first height H1. In some implementations, the first height H1 may be a distance to a lower surface GS1_BS of the first gate structure GS1 based on the upper surface 110US of the first substrate 110.

The second lower pattern BP2 may have a second height H2. The second height H2 may be a distance to a lower surface GS2_BS of the second gate structure GS2 based on the upper surface 211US of the second lower interlayer insulating layer 211. A first height H1 is lower than the second height H2.

In a region overlapped with the first gate structure GS1, the first trench FT1 may have a first depth. The first depth may be substantially the same as the first height H1. In a region overlapped with the second gate structure GS2, the second trench FT2 may have a second depth. The second depth may be substantially the same as the second height H2. In some implementations, the second depth of the second trench FT2 is greater than the first depth of the first trench FT1.

Each of the lower patterns BP1, BP2, BP3 and BP4 may be formed by etching a portion of the substrate 100 or may include an epitaxial layer grown from the substrate 100. Each of the lower patterns BP1, BP2, BP3 and BP4 may include silicon or germanium, which is an elemental semiconductor material. Each of the lower patterns BP1, BP2, BP3 and BP4 may include a compound semiconductor, and may include, for example, a group IV-IV compound semiconductor or a group III-V compound semiconductor. The group IV-IV compound semiconductor may be a binary compound or ternary compound, which includes at least two of carbon (C), silicon (Si), germanium (Ge) or tin (Sn), or a compound including at least two of carbon (C), silicon (Si), germanium (Ge) or tin (Sn), which are doped with a group IV element. The group III-V compound semiconductor may be, for example, one of a binary compound, a ternary compound or a quaternary compound, which is formed by combination of at least one of aluminum (Al), gallium (Ga) or indium (In), which is a group III element, and one of phosphorus (P), arsenic (As) and antimony (Sb), which are group V elements.

Each of the sheet patterns NS1 and NS2 may include one of silicon or germanium, which is an elemental semiconductor material, a group IV-IV compound semiconductor or a group III-V compound semiconductor. In some implementations, a width of the first sheet pattern NS1 in the second direction D2 may be increased or decreased in proportion to a width of the first lower pattern BP1 in the second direction D2. The first sheet patterns NS1 disposed on the first lower pattern BP1 are shown as having the same width in the second direction D2, but are not limited thereto.

A first field insulating layer 105 is disposed on the first substrate 110. In some implementations, the first field insulating layer 105 may be disposed on the first surface 110US of the first substrate 110. The first field insulating layer 105 may fill at least a portion of the first trench FT1 that separates the first and third lower patterns BP1 and BP3.

A second field insulating layer 205 is disposed on the second lower interlayer insulating layer 211. In some implementations, the second field insulating layer 205 may be disposed on the third surface 211US of the second lower interlayer insulating layer 211. The second field insulating layer 205 may fill at least a portion of the second trench FT2 that separates the second and fourth lower patterns BP2 and BP4.

In some implementations, the first field insulating layer 105 may cover all sidewalls of the first and third lower patterns BP1 and BP3. The second field insulating layer 205 may cover all sidewalls of the second and fourth lower patterns BP2 and BP4. In some implementations, the first field insulating layer 105 may cover a portion of the sidewalls of the first and third lower patterns BP1 and BP3. The second field insulating layer 205 may cover a portion of the sidewalls of the second and fourth lower patterns BP2 and BP4. In some implementations, a portion of the first and third lower patterns BP1 and BP3 may be more protruded in the third direction D3 than an upper surface of the first field insulating layer 105. A portion of the second and fourth lower patterns BP2 and BP4 may be more protruded in the third direction D3 than an upper surface of the second field insulating layer 205.

Each of the first field insulating layer 105 and the second field insulating layer 205 may include, for example, an oxide layer, a nitride layer, an oxynitride layer or their combination layer. Each of the first field insulating layer 105 and the second field insulating layer 205 is shown as a single layer for convenience.

The first gate structure GS1 may be disposed on the upper surface 110US of the first substrate 110. The first gate structure GS1 may be extended in the second direction D2. The first gate structure GS1 may cross the first lower pattern BP1. The first gate structure GS1 may surround each of the first sheet patterns NS1. The first gate structure GS1 may be disposed on the first active pattern AP1.

The second gate structure GS2 may be disposed on the upper surface 211US of the second lower interlayer insulating layer 211. The second gate structure GS2 may be extended in the second direction D2. The second gate structure GS2 may cross the second lower pattern BP2. The second gate structure GS2 may surround each of the second sheet patterns NS2. The second gate structure GS2 may be disposed on the second active pattern AP2.

The first gate structure GS1 may include, for example, a first gate electrode 120, a first gate insulating layer 130, a first gate spacer 140 and a first gate capping pattern 145. The second gate structure GS2 may include, for example, a second gate electrode 220, a second gate insulating layer 230, a second gate spacer 240 and a second gate capping pattern 245.

The lower surface GS1_BS of the first gate structure GS1 and the lower surface GS2_BS of the second gate structure GS2 may be disposed on the same plane. In some implementations, based on an upper surface of the first gate structure GS1, a distance to the lower surface GS1_BS of the first gate structure GS1 may be the same as a distance to the lower surface GS2_BS of the second gate structure GS2.

The distance from the second surface 110BS of the first substrate 110 to the lower surface GS1_BS of the first gate structure GS1 and the distance from the upper surface 211US of the second lower interlayer insulating layer 211 to the lower surface GS2_BS of the second gate structure GS2 may be the same as each other. The distance from the second surface 110BS of the first substrate 110 to an upper surface of the first lower pattern BP1 and the distance from the upper surface 211US of the second lower interlayer insulating layer 211 to an upper surface of the second lower pattern BP2 may be the same as each other. The upper surface of the first lower pattern BP1 may be in contact with the lower surface GS1_BS of the first gate structure GS1. The upper surface of the second lower pattern BP2 may be in contact with the lower surface GS2_BS of the second gate structure GS2.

The first gate structure GS1 may include a plurality of first inner gate structures INT_GS1 disposed between the first sheet patterns NS1 adjacent to each other in the third direction D3 and between the first lower pattern BP1 and the first sheet pattern NS1. The first inner gate structure INT_GS1 may be disposed between the upper surface of the first lower pattern BP1 and a lower surface of the first sheet pattern NS1 and between an upper surface of the first sheet pattern NS1 and the lower surface of the first sheet pattern NS1, which face each other in the third direction D3. The number of the first inner gate structures INT_GS1 may be the same as the number of the first sheet patterns NS1. The first inner gate structure INT_GS1 is in contact with the upper surface of the first lower pattern BP1, the upper surface of the first sheet pattern NS1 and the lower surface of the first sheet pattern NS1.

The first inner gate structure INT_GS1 includes a first gate electrode 120 and a first gate insulating layer 130, which are disposed between the first sheet patterns NS1 adjacent to each other and between the first lower pattern BP1 and the first sheet pattern NS1. Although not shown, the first inner gate structure INT_GS1 may be disposed between the third sheet patterns adjacent to each other in the third direction D3 and between the third lower pattern BP3 and the third sheet pattern.

The second gate structure GS2 may include a plurality of second inner gate structures INT_GS2 disposed between the second sheet patterns NS2 adjacent to each other in the third direction D3 and between the second lower pattern BP2 and the second sheet pattern NS2. Although not shown, the second inner gate structure INT_GS2 may be disposed between the fourth sheet patterns adjacent to each other in the third direction D3 and between the fourth lower pattern BP4 and the fourth sheet pattern. The second inner gate structure INT_GS2 may be substantially the same as the first inner gate structure INT_GS1.

The first gate electrode 120 may be disposed on the first lower pattern BP1. The first gate electrode 120 may cross the first lower pattern BP1. The first gate electrode 120 may surround each of the first sheet patterns NS1.

In FIG. 3, an upper surface of the first gate electrode 120 is shown having a concave curved surface, but is not limited thereto. In some implementations, the upper surface of the first gate electrode 120 may include a flat surface. The second gate electrode 220 may be substantially the same as the first gate electrode 120.

The first gate electrode 120 and the second gate electrode 220 may include at least one of a metal, a metal alloy, a conductive metal nitride, a metal silicide, a doped semiconductor material, a conductive metal oxide or a conductive metal oxynitride. The first gate electrode 120 and the second gate electrode 220 may include at least one of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), ruthenium (Ru), titanium aluminum (TiAl), titanium aluminum carbonitride (TiAICN), titanium aluminum carbide (TiAIC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or their combination, but is not limited thereto. In some implementations, the conductive metal oxide and the conductive metal oxynitride may include an oxidized form of the above-described materials, but are not limited thereto.

The first gate insulating layer 130 may extend along the upper surface of the first field insulating layer 105 and the upper surface of the first lower pattern BP1. The first gate insulating layer 130 may surround the plurality of first sheet patterns NS1. The first gate insulating layer 130 may be disposed along the periphery of the first sheet pattern NS1. The first gate electrode 120 is disposed on the first gate insulating layer 130.

The first gate insulating layer 130 is disposed between the first gate electrode 120 and the first sheet pattern NS1. In some implementations, the first gate insulating layer 130 included in the first inner gate structure INT_GS1 may be in contact with the first source/drain pattern 150, as described below. In some implementations, the second gate insulating layer 230 may be substantially the same as the first gate insulating layer 130.

The first gate insulating layer 130 and the second gate insulating layer 230 may include silicon oxide, silicon oxynitride, silicon nitride or a high dielectric constant (high-k) material having a dielectric constant greater than that of silicon oxide. The high dielectric constant material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

Each of the first gate insulating layer 130 and the second gate insulating layer 230 is shown as a single layer for convenience, but each of the first gate insulating layer 130 and the second gate insulating layer 230 may include a plurality of layers. In some implementations, the first gate insulating layer 130 may include an interfacial layer disposed between the first active pattern AP1 and the first gate electrode 120 and between the third active pattern AP3 and the first gate electrode 120, and a high dielectric constant insulating layer. In some implementations, the interfacial layer may not be formed along a profile of the upper surface of the first field insulating layer 105.

In some implementations, the semiconductor device may include a negative capacitance (NC) FET based on a negative capacitor. For example, the first gate insulating layer 130 and the second gate insulating layer 230 may include a ferroelectric material layer having ferroelectric characteristics and a paraelectric material layer having paraelectric characteristics.

The ferroelectric material layer may have a negative capacitance, and the paraelectric material layer may have a positive capacitance. For example, when two or more capacitors are connected in series, and the capacitance of each capacitor has a positive value, the total capacitance is more reduced than the capacitance of each individual capacitor. On the other hand, when at least one of capacitances of two or more capacitors connected in series has a negative value, the total capacitance may have a positive value and may be greater than an absolute value of each individual capacitance.

When a ferroelectric material layer having a negative capacitance and a paraelectric material layer having a positive capacitance are connected in series, the total capacitance value of the ferroelectric material layer and the paraelectric material layer, which are connected in series, may be increased. Based on the total capacitance value that is increased, a transistor having a ferroelectric material layer may have a subthreshold swing (SS) less than 60 mV/decade at a room temperature.

The ferroelectric material layer may have ferroelectric characteristics. The ferroelectric material layer may include at least one of, for example, hafnium oxide, hafnium zirconium oxide, barium strontium titanium oxide, barium titanium oxide, or lead zirconium titanium oxide. In this case, for example, the hafnium zirconium oxide may be a material doped with zirconium (Zr) in hafnium oxide. For another example, the hafnium zirconium oxide may be a compound of hafnium (Hf) and zirconium (Zr) and oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). A type of the dopant included in the ferroelectric material layer may be varied depending on the ferroelectric material of the ferroelectric material layer.

When the ferroelectric material layer includes hafnium oxide, the dopant included in the ferroelectric material layer may include at least one of gadolinium (Gd), silicon (Si), zirconium (Zr), aluminum (Al), or yttrium (Y). When the dopant is aluminum (Al), the ferroelectric material layer may include aluminum of 3 at % to 8 at % (atomic %). In some implementations, a ratio of the dopant may be a ratio of aluminum to a sum of hafnium and aluminum. When the dopant is silicon (Si), the ferroelectric material layer may include silicon of 2 at % to 10 at %. When the dopant is yttrium (Y), the ferroelectric material layer may include yttrium of 2 at % to 10 at %. When the dopant is gadolinium (Gd), the ferroelectric material layer may include gadolinium of 1 at % to 7 at %. When the dopant is zirconium (Zr), the ferroelectric material layer may include zirconium of 50 at % to 80 at %.

The paraelectric material layer may have paraelectric characteristics. The paraelectric material layer may include at least one of, for example, silicon oxide or metal oxide having a high dielectric constant. The metal oxide included in the paraelectric material layer may include, but is not limited to, at least one of hafnium oxide, zirconium oxide, or aluminum oxide.

The ferroelectric material layer and the paraelectric material layer may include the same material. Although the ferroelectric material layer has ferroelectric characteristics, the paraelectric material layer may not have ferroelectric characteristics. For example, when the ferroelectric material layer and the paraelectric material layer include hafnium oxide, a crystal structure of hafnium oxide included in the ferroelectric material layer is different from that of hafnium oxide included in the paraelectric material layer.

The ferroelectric material layer may have a thickness having ferroelectric characteristics. The thickness of the ferroelectric material layer may be, for example, 0.5 nm to 10 nm, but is not limited thereto. Since a threshold thickness indicating ferroelectric characteristics may be varied depending on each ferroelectric material, the thickness of the ferroelectric material layer may be varied depending on the ferroelectric material.

In some implementations, the first gate insulating layer 130 and the second gate insulating layer 230 may include one ferroelectric material layer. In some implementations, the first gate insulating layer 130 and the second gate insulating layer 230 may include a plurality of ferroelectric material layers spaced apart from each other. The first gate insulating layer 130 and the second gate insulating layer 230 may have a stacked layer structure in which a plurality of ferroelectric material layers and a plurality of paraelectric material layers are alternately stacked.

The first gate spacer 140 may be disposed on a sidewall of the first gate electrode 120. In some implementations, the first gate spacer 140 may be disposed on a long sidewall of the first gate electrode 120 extended in the second direction D2. The first gate spacer 140 may not be disposed between the first lower pattern BP1 and the first sheet pattern NS1 and between the first sheet patterns NS1 adjacent to each other in the third direction D3.

The second gate spacer 240 may be substantially the same as the first gate spacer 140. The first gate spacer 140 and the second gate spacer 240 may include at least one of, for example, silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC) or their combination. Each of the first gate spacer 140 and the second gate spacer 240 is shown as a single layer for convenience, but is not limited thereto.

The first gate capping pattern 145 may be disposed on the first gate electrode 120. An upper surface of the first gate capping pattern 145 may be the upper surface of the first gate structure GS1. The second gate capping pattern 245 may be disposed on the second gate electrode 220. An upper surface of the second gate capping pattern 245 may be an upper surface of the second gate structure GS2.

In some implementations, the first gate capping pattern 145 may be disposed between the first gate spacers 140. The second gate capping pattern 245 may be disposed between the second gate spacers 240. The first gate capping pattern 145 and the second gate capping pattern 245 may include at least one of, for example, silicon nitride (SiN), silicon oxynitride (SiON), silicon carbonitride (SiCN), silicon oxycarbonitride (SiOCN) or their combination.

In some implementations, the first gate structure GS1 and the second gate structure GS2 may not include the gate capping patterns 145 and 245.

The first source/drain pattern 150 may be disposed on the first lower pattern BP1. The first source/drain pattern 150 may be disposed on sides of the first gate electrode 120. The first source/drain pattern 150 may be in contact with the first active pattern AP1. The first source/drain pattern 150 may be in contact with the first sheet pattern NS1. The first source/drain pattern 150 is connected to the first sheet pattern NS1 and the first lower pattern BP1. In some implementations, the first source/drain pattern 150 may be in contact with the first inner gate structure INT_GS1.

The second source/drain pattern 250 may be disposed on the second lower pattern BP2. The second source/drain pattern 250 may be disposed on sides of the second gate electrode 220. The second source/drain pattern 250 may be in contact with the second active pattern AP2. The second source/drain pattern 250 may be in contact with the second sheet pattern NS2. The second source/drain pattern 250 is connected to the second sheet pattern NS2 and the second lower pattern BP2. In some implementations, the second source/drain pattern 250 may be in contact with the second inner gate structure INT_GS2.

A third source/drain pattern 151 may be disposed on the third lower pattern BP3. The third source/drain pattern 151 may be disposed on the sides of the first gate electrode 120. A fourth source/drain pattern 251 may be disposed on the fourth lower pattern BP4. The fourth source/drain pattern 251 may be disposed on the sides of the second gate electrode 220. Although not shown, the third source/drain pattern 151 may be in contact with the third sheet pattern. The fourth source/drain pattern 251 may be in contact with the fourth sheet pattern.

In some implementations, the cross-section taken in the first direction D1 along the third active pattern AP3 and the fourth active pattern AP4 may be similar to that of FIG. 2. The third source/drain pattern 151 may be in contact with the first gate insulating layer 130 included in the first inner gate structure INT_GS1. The fourth source/drain pattern 251 may be in contact with the second gate insulating layer 230 included in the second inner gate structure INT_GS2.

The source/drain patterns 150, 151, 250, and 251 may be disposed on the first surface 110US of the first substrate 110. Since the first lower pattern BP1 is spaced apart from the third lower pattern BP3 in the second direction D2, the first source/drain pattern 150 is spaced apart from the third source/drain pattern 151 in the second direction D2. The second source/drain pattern 250 is spaced apart from the fourth source/drain pattern 250 in the second direction D2.

The first source/drain pattern 150 may be included in a source/drain of a transistor that uses the first sheet pattern NS1 as a channel region. The second source/drain pattern 250 may be included in a source/drain of a transistor that uses the second sheet pattern NS2 as a channel region. The third source/drain pattern 151 may be included in a source/drain of a transistor that uses the third sheet pattern NS3 as a channel region. The fourth source/drain pattern 251 may be included in a source/drain of a transistor that uses a fourth sheet pattern as a channel region.

Each of the source/drain patterns 150, 151, 250, and 251 may include an epitaxial pattern. Each of the source/drain patterns 150, 151, 250, and 251 may include a semiconductor material. The first source/drain pattern 150 may include a p-type dopant. The p-type dopant may include, but is not limited to, at least one of boron (B) or gallium (Ga). The third source/drain pattern 151 may include an n-type dopant. The n-type dopant may include at least one of phosphorus (P), arsenic (As), antimony (Sb) or bismuth (Bi), but is not limited thereto.

A first source/drain etching stop layer 157 may be extended along outer sidewalls of the first gate spacer 140 and sidewalls of the first source/drain pattern 150. The first source/drain etching stop layer 157 may be extended along the upper surface of the first field insulating layer 105. A third source/drain etching stop layer 158 may be extended along sidewalls of the third gate spacer and the sidewalls of the first source drain pattern 151. The first source/drain etching stop layer 157 and the third source/drain etching stop layer 158 may be connected to the upper surface of the first field insulating layer 105.

The second source/drain etching stop layer 257 may be substantially the same as the first source/drain etching stop layer 157. The fourth source/drain etching stop layer 258 may be substantially the same as the third source/drain etching stop layer 158.

Each of the source/drain etching stop layers 157, 158, 257, and 258 may include at least one of, for example, silicon nitride (SiN), silicon oxynitride (SiON), silicon oxycarbonitride (SiOCN), silicon boron nitride (SiBN), silicon oxyboron nitride (SiOBN), silicon oxycarbide (SiOC) or their combination.

The first upper interlayer insulating layer 190 is disposed on the first surface 110US of the first substrate 110. The first upper interlayer insulating layer 190 may be disposed on the first source/drain pattern 150 and the third source/drain pattern 151. The first upper interlayer insulating layer 190 may be disposed on the first source/drain etching stop layer 157 and the third source/drain etching stop layer 158.

The first upper interlayer insulating layer 190 may not cover the upper surface of the first gate capping pattern 145. The first upper interlayer insulating layer 190 may include at least one of, for example, silicon oxide, silicon nitride, silicon oxynitride or a low dielectric constant material. A dielectric constant of the low dielectric constant material may have a value smaller than 3.9 that is the dielectric constant of the silicon oxide. The second upper interlayer insulating layer 290 may be substantially the same as the first upper interlayer insulating layer 190.

The first source/drain contact 170 may be disposed on the upper surface 110US of the first substrate 110. The first source/drain contact 170 may be disposed on the first source/drain pattern 150. The first source/drain contact 170 is electrically connected to the first source/drain pattern 150.

The first source/drain contact 170 may be connected to the first rear wiring line 50 through the first contact connection via 180. The first source/drain contact 170 may be directly in contact with the first contact connection via 180. In some implementations, the first source/drain contact 170 may not be directly in contact with the first contact connection via 180. For example, the first source/drain contact 170 may be electrically connected to the first contact connection via 180 through an upper wiring line thereof.

The third source/drain contact 171 may be disposed on the upper surface 110US of the first substrate 110. The third source/drain contact 171 may be disposed on the third source/drain pattern 151. The third source/drain contact 171 is electrically connected to the third source/drain pattern 151.

The third source/drain contact 171 may be connected to the third rear wiring line 55 through a third contact connection via 182. The third source/drain contact 171 may be directly in contact with the third contact connection via 182, but is not limited thereto.

The second source/drain contact 270 may be disposed on the upper surface 211US of the second lower interlayer insulating layer 211. The second source/drain contact 270 may be disposed on the second source/drain pattern 250. The second source/drain contact 270 is electrically connected to the second source/drain pattern 250.

The second source/drain contact 270 may be connected to the second rear wiring line 60 through the second contact connection via 280. The second source/drain contact 270 may be directly in contact with the second contact connection via 280. In some implementations, the second source/drain contact 270 may not be directly in contact with the second contact connection via 280. For example, the second source/drain contact 270 may be electrically connected to the second contact connection via 280 through an upper wiring line thereof.

The fourth source/drain contact 271 may be disposed on the upper surface 211US of the second lower interlayer insulating layer 211. The fourth source/drain contact 271 may be disposed on the fourth source/drain pattern 251. The fourth source/drain contact 271 is electrically connected to the fourth source/drain pattern 251.

The fourth source/drain contact 271 may be connected to a fourth rear wiring line 65 through a fourth contact connection via 282. The fourth source/drain contact 271 may be directly in contact with the fourth contact connection via 282, but is not limited thereto.

A first contact silicide layer 155 may be disposed between the first source/drain contact 170 and the first source/drain pattern 150. A third contact silicide layer 156 may be disposed between the third source/drain contact 171 and the third source/drain pattern 151. A second contact silicide layer 255 may be disposed between the second source/drain contact 270 and the second source/drain pattern 250. A fourth contact silicide layer 256 may be disposed between the fourth source/drain contact 271 and the fourth source/drain pattern 251.

The source/drain contacts 170, 171, 270, and 271 are shown as having a single conductive layer structure, but are not limited thereto. In some implementations, the source/drain contacts 170, 171, 270, and 271 may have a multi-conductive layer structure that includes a contact barrier layer and a plug layer.

A first rear wiring contact 52 may be disposed in the first substrate 110. One surface of the first rear wiring contact 52 may be connected to the first contact connection via 180. The other surface of the first rear wiring contact 52 may be connected to a first rear wiring via 51. The first rear wiring contact 52 may electrically connect the first contact connection via 180 with the first rear wiring via 51. A second rear wiring contact 57 may be disposed in the first substrate 110. The second rear wiring contact 57 may electrically connect the third contact connection via 182 with a third rear wiring via 56.

For the second active pattern AP2, the second contact connection via 280 may be connected to a second rear wiring via 61, unlike the first active pattern AP1. The second rear wiring via 61 may be connected to the second rear wiring line 60. For the fourth active pattern AP4, the fourth contact connection via 282 may be connected to a fourth rear wiring via 66. The fourth rear wiring via 66 may be connected to the fourth rear wiring line 65.

The rear wiring lines 50, 55, 60, and 65 may be formed at the same level, in which the same level may refer to the same manufacturing process. The rear wiring lines 50, 55, 60, and 65 may be extended in the first direction D1, but is not limited thereto.

A first gate contact 175 is disposed on the first gate electrode 120. The first gate contact 175 may pass through the first gate capping pattern 145. The first gate contact 175 is connected to the first gate electrode 120. The first gate contact 175 connects a first front wiring structure 195 with the first gate electrode 120. The first front wiring structure 195 may include a first front wiring via 196 and a first front wiring line 197.

A second gate contact 275 is disposed on the second gate electrode 220. The second gate contact 275 may pass through the second gate capping pattern 245. The second gate contact 275 is connected to the second gate electrode 220. The second gate contact 275 connects a second front wiring structure 295 with the second gate electrode 220. The second front wiring structure 295 may include a second front wiring via 296 and a second front wiring line 297.

The first gate contact 175 and the second gate contact 275 are shown as having a single conductive layer structure, but are not limited thereto. In some implementations, the first gate contact 175 and the second gate contact 275 may have a multi-conductive layer structure that includes a barrier layer and a plug layer.

The source/drain contacts 170, 171, 270, and 271 and the gate contacts 175 and 275 may include at least one of, for example, a metal, a conductive metal nitride, a conductive metal carbide, a conductive metal oxide, a conductive metal carbonitride or a two-dimensional (2D) material. The contact silicide layers 155, 156, 255, and 256 may include a metal silicide material.

The two-dimensional (2D) material may include a two-dimensional allotrope or a two-dimensional compound, and may include at least one of, for example, graphene, boron nitride (BN), molybdenum sulfide, molybdenum selenide, tungsten sulfide, tungsten selenide or tantalum sulfide, but is not limited thereto. That is, the two-dimensional materials described above are exemplary, and the two-dimensional materials that may be included in the semiconductor device of the present disclosure are not limited by the above-described materials.

A first connection via liner 181 may be disposed on sidewalls of the first contact connection via 180. A second connection via liner 281 may be disposed on sidewalls of the second contact connection via 280. A third connection via liner 183 may be disposed on sidewalls of the third contact connection via 182. A fourth connection via liner 283 may be disposed on sidewalls of the fourth contact connection via 282.

The contact connection vias 180, 182, 280, and 282 are shown as having a single conductive layer structure, but are not limited thereto. In some implementations, the contact connection vias 180, 182, 280, and 282 may have a multi-conductive layer structure. The contact connection vias 180, 182, 280, and 282 may include at least one of, for example, a metal, a conductive metal nitride, a conductive metal carbide, a conductive metal oxide, a conductive metal carbonitride or a two-dimensional material.

The first connection via liner 181 may include at least one of, for example, silicon nitride (SiN), silicon oxynitride (SiON), silicon oxycarbonitride (SiOCN), silicon boron nitride (SiBN), silicon oxyboron nitride (SiOBN), silicon oxycarbide (SiOC) or their combination.

The third upper interlayer insulating layer 191 may be disposed on the first upper interlayer insulating layer 190, the first gate structure GS1, the first source/drain contact 170, and the first contact connection via 180. The third upper interlayer insulating layer 191 may include at least one of, for example, silicon oxide, silicon nitride, silicon oxynitride or a low dielectric constant material. The fourth upper interlayer insulating layer 291 may be substantially the same as the third upper interlayer insulating layer 191.

The first front wiring structure 195 may be disposed in the third upper interlayer insulating layer 191. The first front wiring structure 195 may be connected to the first source/drain contact 170 and the first gate contact 175. The second front wiring structure 295 may be disposed in the fourth upper interlayer insulating layer 291. The second front wiring structure 295 may be connected to the second source/drain contact 270 and the second gate contact 275.

Each of the first front wiring via 196 and the first front wiring line 197 may include at least one of, for example, a metal, a conductive metal nitride, a conductive metal carbide, a conductive metal oxide, a conductive metal carbonitride or a two-dimensional material. Each of the first front wiring via 196 and the first front wiring line 197 is shown as a single conductive layer structure, but is not limited thereto. In some implementations, at least one of the first front wiring via 196 or the first front wiring line 197 may have a multi-conductive layer structure. In some implementations, the first front wiring structure 195 may have an integral structure in which a boundary surface is not distinguished between the front wiring via 196 and the front wiring line 197.

The second front wiring via 296 and the second front wiring line 297 may be substantially the same as the first front wiring via 196 and the first front wiring line 197.

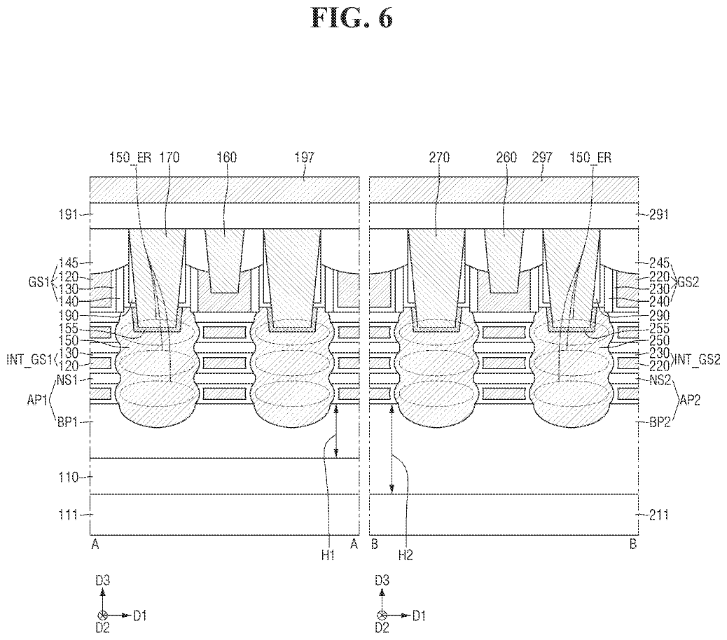

FIG. 6 is a view illustrating a semiconductor device according to some implementations. For convenience of description, the following description will be based on differences from the description made with reference to FIGS. 1-5.

In FIG. 6, each of the sidewalls of the first source/drain pattern 150 and the sidewalls of the second source/drain pattern 250 have a wavy shape. Each of the first source/drain pattern 150 and the second source/drain pattern 250 may include a plurality of width extension regions 150_ER. The width extension region 150R_ER of the first source/drain pattern 150 may be defined above the upper surface of the first lower pattern BP1. The width extension region 150R_ER of the second source/drain pattern 250 may be defined above the upper surface of the second lower pattern BP2.

Since the width extension region 150_ER of the second source/drain pattern 250 may be substantially the same as the first source/drain pattern 150, the following description will be based on the first source/drain pattern 150.

The width extension region 150_ER of the first source/drain pattern 150 may be defined between first sheet patterns NS1 adjacent to each other in the third direction D3. The width extension region 150_ER of the first source/drain pattern 150 may be defined between the first lower pattern BP1 and the first sheet pattern NS1. The width extension region 150_ER of the first source/drain pattern 150 may be extended between the first inner gate structures INT_GS1 adjacent to each other in the first direction D1.

As the width extension region 150_ER of each of the first source/drain pattern 150 extends from the upper surface of the first lower pattern BP1, the width extension region 150_ER may include a portion in which a width in the first direction D1 is increased and a portion in which a width in the first direction D1 is reduced. In some implementations, as the width extension region 150_ER of the first source/drain pattern 150 extends from the upper surface of the first lower pattern BP1, the width of the width extension region 150_ER of the first source/drain pattern 150 may be increased and then reduced. The width extension region 150_ER of the first source/drain pattern 150 is shown as having a uniform width in the first direction D1, but is not limited thereto.

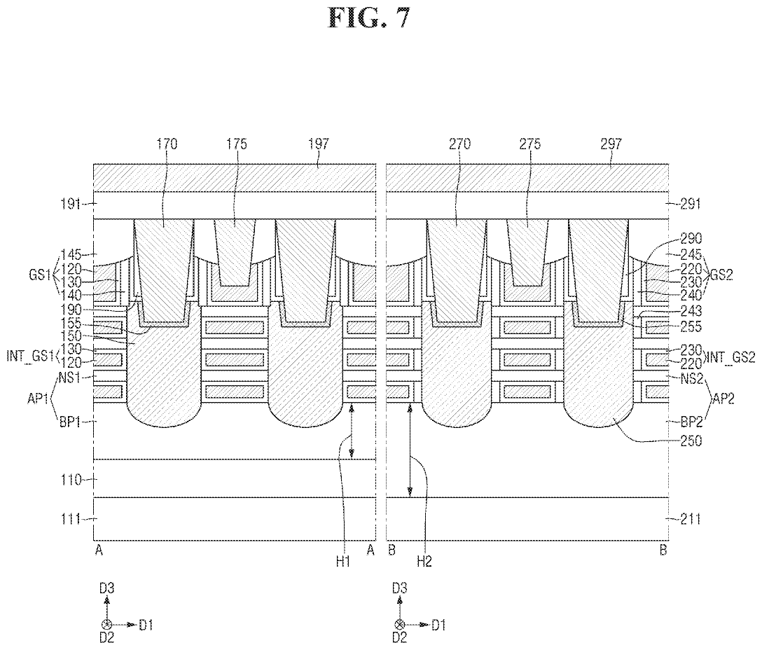

FIG. 7 is a view illustrating a semiconductor device according to some implementations. For convenience of description, the following description will be based on differences from the description made with reference to FIGS. 1-5.

In FIG. 7, the semiconductor device according to some implementations further includes an inner spacer 243 disposed between the second gate structure GS2 and the second source/drain pattern 250. The inner spacer 243 may be disposed between the second inner gate structure INT_GS2 and the second source/drain pattern 250. Sidewalls of a recess of the second source/drain pattern 250 may be defined by the inner spacer 243. The inner spacer 243 may be in contact with second inner gate structure INT_GS2. The inner spacer 243 may be in contact with the second source/drain pattern 250. In some implementations, the inner spacer 243 may be disposed between the first gate structure GS1 and the first source/drain pattern 150. The inner spacer 243 may include at least one of, for example, silicon nitride (SiN), silicon oxynitride (SiON), silicon oxycarbonitride (SiOCN), silicon boron nitride (SiBN), silicon oxyboron nitride (SiOBN), silicon oxycarbide (SiOC) or their combination.

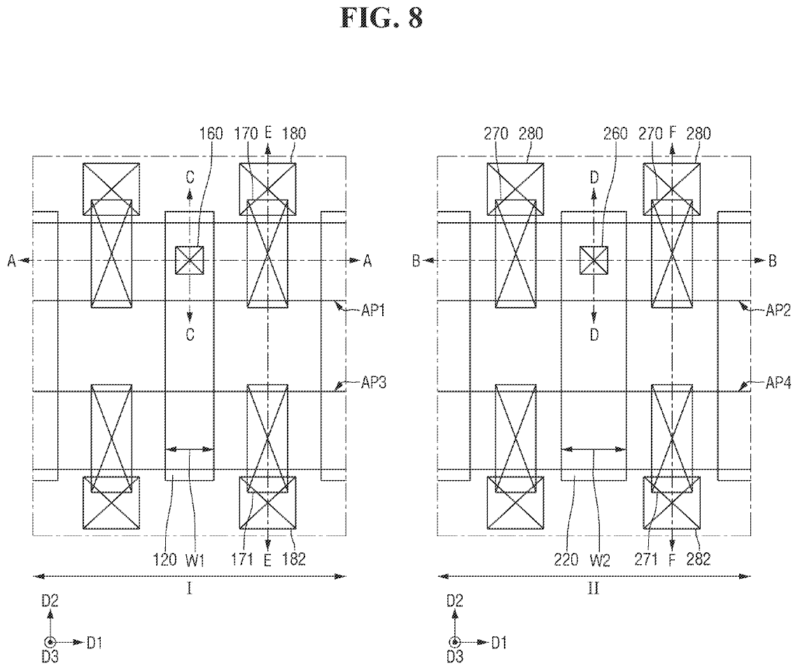

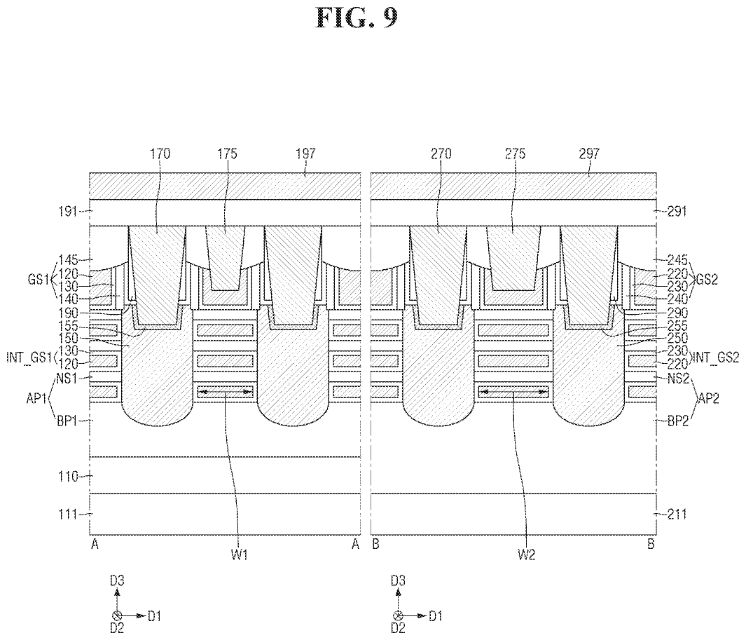

FIGS. 8-10 are views illustrating a semiconductor device according to some implementations. For convenience of description, the following description will be based on differences from the description made with reference to FIGS. 1-5.

In FIGS. 8-10, a width of the first gate structure GS1 in the first direction D1 is smaller than a width of the second gate structure GS2 in the first direction D1.

The first gate electrode 120 may have a first width W1 in the first direction D1. The second gate electrode 220 may have a second width W2 in the first direction D1. The second width W2 is greater than the first width W1. A thickness of the first gate insulating layer 130 and a thickness of the second gate insulating layer 230 may be the same as each other. Accordingly, the width of the first gate structure GS1 is smaller than the width of the second gate structure GS2.

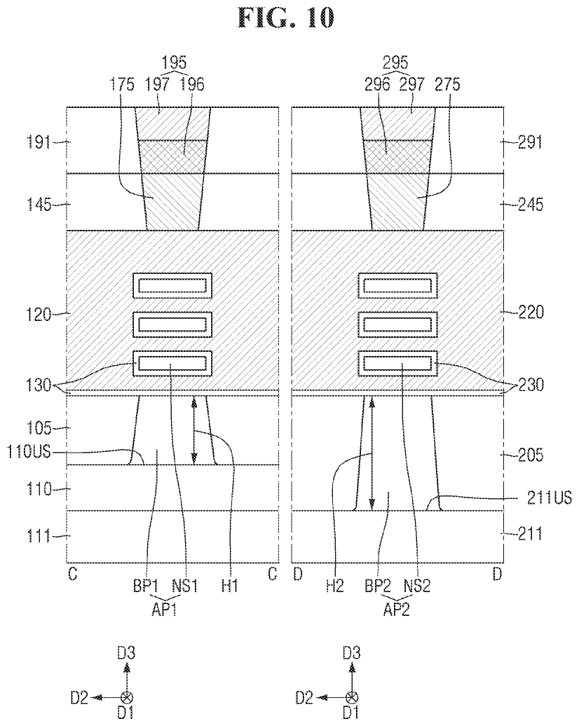

In FIG. 10, a width of the first sheet pattern NS1 in the second direction D2 and a width of the second sheet pattern NS2 in the second direction D2 are shown as being the same as each other, but the present disclosure is not limited thereto. In some implementations, the width of the second sheet pattern NS2 in the second direction D2 may be greater than the width of the first sheet pattern NS1 in the second direction D2. In some implementations, the width of the second sheet pattern NS2 in the second direction D2 may be smaller than the width of the first sheet pattern NS1 in the second direction D2.

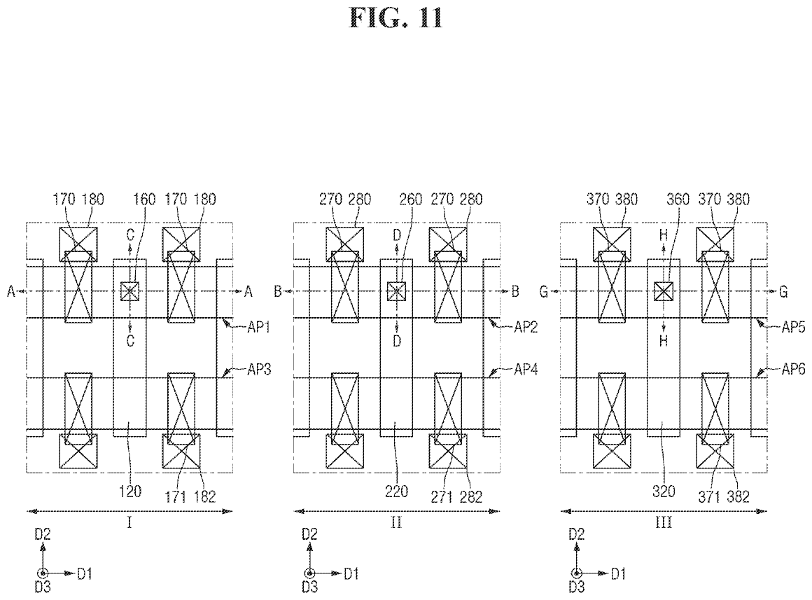

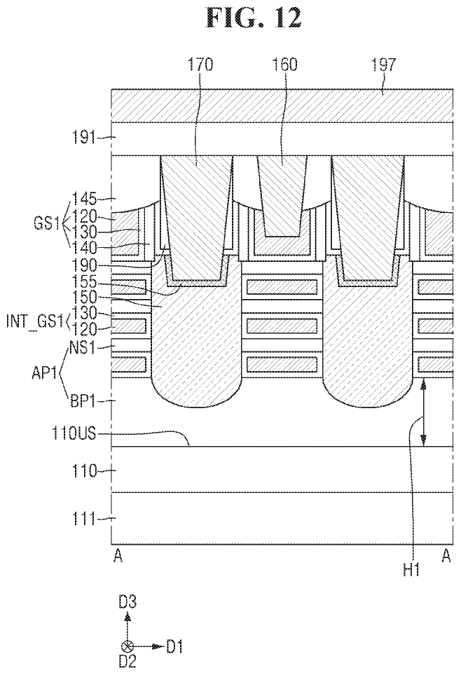

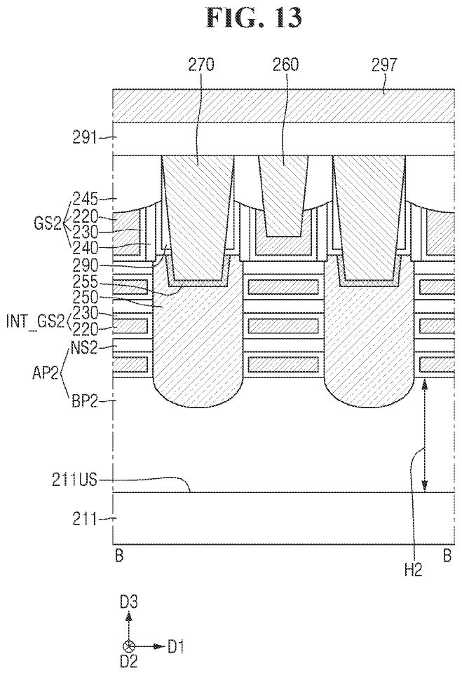

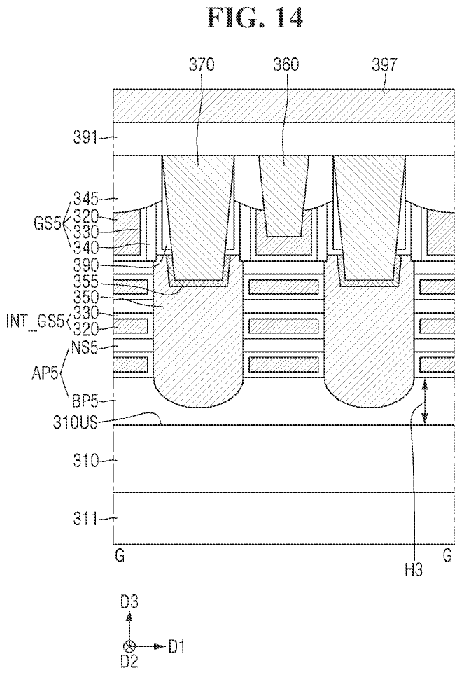

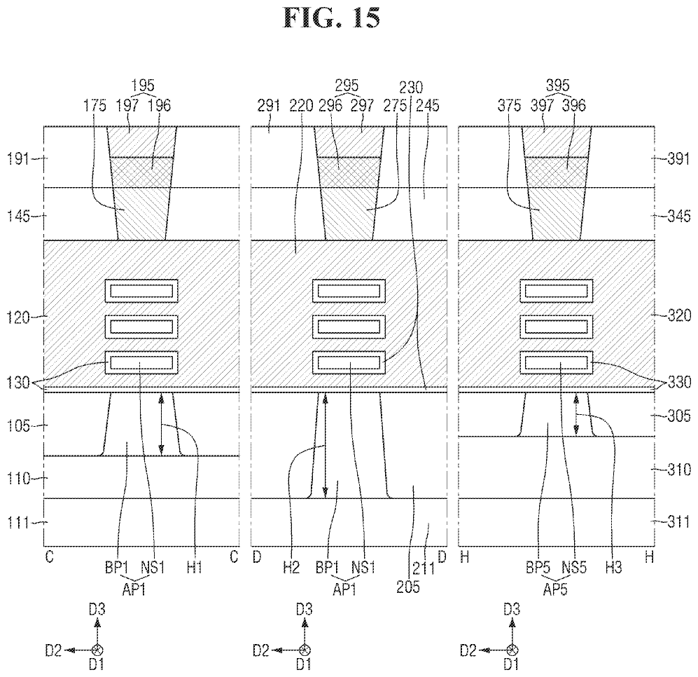

FIGS. 11-15 are views illustrating a semiconductor device according to some implementations. For convenience of description, the following description will be based on differences from the description made with reference to FIGS. 1-5.

In FIGS. 11-15, the semiconductor device further includes a fifth active pattern AP5, a sixth active pattern AP6, a second substrate 310, a third lower interlayer insulating layer 311, a fifth gate structure GS5, a fifth source/drain pattern 350, and a fifth source/drain contact 370.

The second substrate 310 may include a first surface 310US and a second surface 310BS, which are opposite to each other in the third direction D3. Since the third gate electrode 320 and the fifth source/drain pattern 350 may be disposed on the first surface 310US of the second substrate 310, the first surface 310US of the second substrate 310 may be an upper surface of the second substrate 310. The second surface 310BS of the second substrate 310, which is opposite to the first surface 310US of the second substrate 310, may be a lower surface of the second substrate 310. In some implementations, the second substrate 310 may include an insulating material. For example, the second substrate 310 may include silicon oxide.

The fifth active pattern AP5 and the sixth active pattern AP6 may be disposed on the second substrate 310. For example, the fifth active pattern AP5 and the sixth active pattern AP6 may be disposed on the upper surface 310US of the second substrate 310. The fifth and sixth active patterns AP5 and AP6 may be extended lengthwise in the first direction D1.

The fifth active pattern AP5 and the sixth active pattern AP6 may be spaced apart from each other in the second direction D2. The fifth active pattern AP5 may be disposed in a region in which a transistor of the same conductivity type is formed. The sixth active pattern AP6 may be disposed in a region in which a transistor of the same conductivity type is formed.

The fifth active pattern AP5 and the sixth active pattern AP6 may be formed in a third region III. In some implementations, the third region III may be a region in which a passive element is formed, but is not limited thereto. For example, the third region III may be a region in which an active element is formed.

The fifth active pattern AP5 may be formed on the upper surface 310US of the second substrate 310. The fifth active pattern AP5 may include a fifth lower pattern BP5 and a fifth sheet pattern NS5. The fifth lower pattern BP5 may be protruded from the upper surface 310US of the second substrate 310.

In some implementations, the fifth lower pattern BP5 and a sixth lower pattern may be separated from each other by a third trench. For example, the upper surface 310US of the second substrate 310 may include a bottom surface of the third trench. Each of the fifth lower pattern BP5 and the sixth lower pattern includes sidewalls extended in the first direction D1. The sidewalls of each of the fifth lower pattern BP5 and the sixth lower pattern may be defined by the third trench. A cross-section view taken along the fifth active pattern AP5 may be similar to that of FIG. 4.

The first lower pattern BP1 may have a first height H1. In this case, the first height H1 may be a distance to the lower surface GS1_BS of the first gate structure GS1 based on the upper surface 110US of the first substrate 110. The second lower pattern BP2 may have a second height H2. The second height H2 may be a distance to the lower surface GS2_BS of the second gate structure GS2 based on the upper surface 211US of the second lower interlayer insulating layer 211. The fifth lower pattern BP5 may have a third height H3. The third height H3 may be a distance to the lower surface GS5_BS of the fifth gate structure GS5 based on the upper surface 310US of the second substrate 310.

In some implementations, the first height H1, the second height H2, and the third height H3 may be different from one another. For example, the second height H2 may be greater than the first height H1, and the first height H1 may be greater than the third height H3.

In a region overlapped with the first gate structure GS1, the first trench FT1 may have a first depth. The first depth may be substantially the same as the first height H1. In a region overlapped with the second gate structure GS2, the second trench FT2 may have a second depth. The second depth may be substantially the same as the second height H2. In a region overlapped with the fifth gate structure GS5, the third trench may have a third depth. The third depth may be substantially the same as the third height H3. In some implementations, the second depth of the second trench FT2 may be greater than the first depth of the first trench FT1, and the first depth of the first trench FT1 may be greater than the third depth of the third trench.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

What is claimed is:

1. A semiconductor device comprising:
a first substrate including a first surface and a second surface opposite to the first surface;
a first lower interlayer insulating layer disposed on the second surface of the first substrate;
a first active pattern including a first lower pattern in contact with the first surface of the first substrate extending in a first direction and a plurality of first sheet patterns spaced apart from the first lower pattern in a second direction;
a first gate structure disposed on the first lower pattern, the first gate pattern surrounding the plurality of first sheet patterns;
a first source/drain pattern disposed on at least one side of the first gate structure;
a second lower interlayer insulating layer including a third surface and a fourth surface opposite to the third surface;
a second active pattern including a second lower pattern in contact with the third surface of the second lower interlayer insulating layer extending in the first direction and a plurality of second sheet patterns spaced apart from the second lower pattern in the second direction;
a second gate structure disposed on the second lower pattern, the second gate structure surrounding the plurality of second sheet patterns; and
a second source/drain pattern disposed on at least one side of the second gate structure,
wherein the first lower pattern has a first height from the first surface of the first substrate, and
the second lower pattern has a second height, different from the first height, from the third surface of the second lower interlayer insulating layer.

2. The semiconductor device of claim 1, wherein the first substrate includes an insulating material.

3. The semiconductor device of claim 1, further comprising a first rear wiring line disposed in the first lower interlayer insulating layer,
wherein the first rear wiring line is connected to the first source/drain pattern.

4. The semiconductor device of claim 3, further comprising:
a first source/drain contact connected to the first source/drain pattern;
a first contact connection via connected to the first source/drain contact; and
a rear wiring contact disposed in the first substrate and connected to the first contact connection via,
wherein the rear wiring contact is connected to the first rear wiring line.

5. The semiconductor device of claim 1, wherein a distance from the second surface of the first substrate to a lower surface of the first gate structure is the same as a distance from the third surface of the second lower interlayer insulating layer to a lower surface of the second gate structure.

6. The semiconductor device of claim 1, further comprising:
a first trench defining the first lower pattern; and
a second trench defining the second lower pattern,
wherein a depth of the first trench is different from a depth of the second trench.

7. The semiconductor device of claim 6, wherein the depth of the first trench is smaller than the depth of the second trench.

8. The semiconductor device of claim 1, wherein a width of the first gate structure in the first direction is different from a width of the second gate structure in the first direction.

9. The semiconductor device of claim 1, wherein, from an upper surface of the first gate structure, a distance to an upper surface of the first lower pattern is the same as a distance to an upper surface of the second lower pattern.

10. The semiconductor device of claim 1, further comprising:
a third lower pattern extending in the first direction;
a plurality of third sheet patterns spaced apart from the third lower pattern in the second direction; and
a third gate structure disposed on the third lower pattern, the third gate structure surrounding the plurality of third sheet patterns,
wherein the third lower pattern has a third height, and
the first, second, and third heights are different from one another.

11. The semiconductor device of claim 1, wherein the second gate structure includes an inner gate structure disposed between the second lower pattern and the second sheet pattern and between adjacent ones of the second sheet patterns, and
wherein the second gate structure includes a gate electrode and a gate insulating layer.

12. The semiconductor device of claim 11, further comprising an inner spacer disposed between the inner gate structure and the second source/drain pattern.

13. The semiconductor device of claim 1, further comprising:
a second source/drain contact connected to the second source/drain pattern; and
a second contact connection via connected to the second source/drain contact,
wherein the second contact connection via is connected to a second rear wiring line in the second lower interlayer insulating layer.

14. A semiconductor device comprising:
a first active pattern including a first lower pattern extending in a first direction and a plurality of first sheet patterns spaced apart from the first lower pattern in a second direction;
a first trench defining the first lower pattern and having a first depth;
a first gate structure disposed on the first lower pattern, the first gate structure surrounding the plurality of first sheet patterns;
a first source/drain pattern disposed on at least one side of the first gate structure;
a second active pattern including a second lower pattern extending in the first direction and a plurality of second sheet patterns spaced apart from the second lower pattern in the second direction;
a second trench defining the second lower pattern and having a second depth greater than the first depth;
a second gate structure disposed on the second lower pattern, the second gate structure surrounding the plurality of second sheet patterns; and
a second source/drain pattern disposed on at least one side of the second gate structure,
wherein a width of the first gate structure in the first direction is smaller than a width of the second gate structure in the first direction.

15. The semiconductor device of claim 14, wherein, from an upper surface of the first gate structure, a distance to an upper surface of the first lower pattern is the same as a distance to an upper surface of the second lower pattern.

16. The semiconductor device of claim 14, wherein a distance from a lowermost portion of the first lower pattern to a lower surface of the first gate structure is smaller than a distance from a lowermost portion of the second lower pattern to a lower surface of the second gate structure.

17. The semiconductor device of claim 14, further comprising a first insulating substrate disposed on a lower surface of the first lower pattern.

18. The semiconductor device of claim 17, wherein the first insulating substrate includes a first surface in contact with the first lower pattern and a second surface opposite to the first surface, and
the first surface of the first insulating substrate includes a bottom surface of the first trench.

19. The semiconductor device of claim 17, further comprising:
a first rear wiring line disposed on the first insulating substrate and connected to the first source/drain pattern; and
a second rear wiring line disposed on the second lower pattern and connected to the second source/drain pattern.

20. A semiconductor device comprising:
a first substrate including a first surface and a second surface opposite to the first surface and including an insulating material;
a first active pattern including a first lower pattern being in contact with the first surface of the first substrate extending in a first direction and a plurality of first sheet patterns spaced apart from the first lower pattern in a second direction;
a first gate structure disposed on the first lower pattern, the first gate structure surrounding the plurality of first sheet patterns;
a first source/drain pattern disposed on at least one side of the first gate structure;
a first lower interlayer insulating layer disposed on the second surface of the first substrate;
a first rear wiring line disposed in the first lower interlayer insulating layer and connected to the first source/drain pattern;
a second lower interlayer insulating layer including a third surface and a fourth surface opposite to the third surface;
a second active pattern including a second lower pattern being in contact with the second lower interlayer insulating layer extending in the first direction and a plurality of second sheet patterns spaced apart from the second lower pattern in the second direction;
a second gate structure disposed on the second lower pattern, the second gate structure surrounding the plurality of second sheet patterns;
a second source/drain pattern disposed on at least one side of the second gate structure; and
a second rear wiring line disposed in the second lower interlayer insulating layer and connected to the second source/drain pattern,
wherein the first lower pattern has a first height based on the first surface of the first substrate,
wherein the second lower pattern has a second height greater than the first height based on the third surface of the second lower interlayer insulating layer, and
wherein, from an upper surface of the first gate structure, a distance to an upper surface of the first lower pattern is the same as a distance to an upper surface of the second lower pattern.
